(19) United States
(12) Patent Application Publication
(10) Pub. No.: US 2008/0053714 A1
(43) Pub. Date: Mar. 6, 2008

(54) INPUT DEVICE AND MANUFACTURING METHOD THEREOF

(76) Inventors: Hideki Ito, Fukushima-ken (JP); Yoshizo Kubo, Fukushima-ken (JP); Junji Hashida, Fukushima-ken (JP); Shinji Hirano, Fukushima-ken (JP); Hideki Suzuki, Tokyo (JP); Yoshihisa Endo, Tokyo (JP); Toshio Kawano, Fukushima-ken (JP); Katsuichi Oba, Fukushima-ken (JP)

Correspondence Address: BRINKS HOFER GILSON & LIONE, P.O. BOX 10395, CHICAGO, IL, 60610, US

(21) Appl. No.: 11/839,933

(22) Filed: Aug. 16, 2007

(30) Foreign Application Priority Data
Aug. 30, 2006 (JP) 2006-234413

(51) Int. Cl. G06K 11/06; H05K 3/30

(52) U.S. Cl. 178/18.06; 29/832

(57) ABSTRACT

An input device and a manufacturing method thereof are provided. The input device includes a conductive film formed on a substrate; electrode sections obtained by cutting and partitioning the conductive film in a predetermined shape so as to correspond to the sensor section; a ground pattern disposed at a position located, in the film thickness direction, opposite a remaining portion of the conductive film excluding the electrode sections; and at least one dividing groove formed on a portion of the remaining conductive film disposed between the ground pattern and the electrode sections, for division of the remaining conductive film.

This application claims the benefit of Japanese Patent Application No. 2006-234413 filed Aug. 30, 2006, the entire contents of which are incorporated herein by reference.

### BACKGROUND

1. Technical Field

The present invention relates to an input device configured to detect touch or approach of an input member such as a user's finger. Moreover, the invention relates to an input device and a manufacturing method thereof capable of improving a reference sensitivity, suppressing fluctuation of the reference sensitivity, improving output characteristics during detection, and thereby improving the stability of an input operation.

2. Description of the Related Art

In the related art, touch sensor related inventions are described in JP-A-2005-339856 and JP-A-2004-146099, for example.

In the touch sensor shown in FIG. 4 of JP-A-2005-339856, a plurality of electrode sections are formed on a substrate.

The touch sensor is incorporated in a casing. When a finger touches the casing, the touch sensor detects a change in electrostatic capacitance between the finger and the electrode sections.

After forming a conductive film on the entire surface of the substrate, the electrode sections are obtained by removing unnecessary portions of the conductive film excluding an electrode formation area of the conductive film by laser irradiation.

However, since a removal width of the laser irradiation is about several tens of micrometers, the laser removal of all the unnecessary conductive film requires a significant amount of time. Thus, manufacturing efficiency deteriorates.

However, it is possible to improve the manufacturing efficiency. without removing all the unnecessary conductive film, by partitioning the conductive film in the form of the electrode sections by laser irradiation and doing nothing on the unnecessary conductive film disposed outside the electrode sections.

However, when the unnecessary conductive film remains in the vicinity of the electrode sections as described above, a floating capacitance component increases. Thus, the reference sensitivity deteriorates or fluctuates and the output characteristics during detection deteriorate.

Here, the “reference sensitivity” is determined by a rise of an output to a time in an initial state when the finger does not touch or approach the touch sensor. The sharper the rise, the higher the reference sensitivity is regarded.

The touch panel is provided with a ground pattern. The ground pattern is formed on a portion of an insulating film corresponding to the remaining conductive film disposed outside the electrode sections. According to experiments described later, the floating capacitance component increases prominently in the vicinity of the ground pattern.

### SUMMARY

An input device is provided having a sensor section configured to detect an electrostatic capacitance change by an input member. The input device includes a conductive film formed on a substrate; electrode sections obtained by cutting and partitioning the conductive film in a predetermined shape so as to correspond to the sensor section. A ground pattern is disposed at a position located, in the film thickness direction, opposite a remaining portion of the conductive film excluding the electrode sections. At least one dividing groove is formed on a portion of the remaining conductive film disposed between the ground pattern and the electrode sections, in order to divide the remaining conductive film.

With this configuration, it is possible to reduce the floating capacitance component and thus to improve a reference sensitivity, suppress fluctuation of the reference sensitivity, improve output characteristics during detection, and thereby assuring a stable input operation.

In particular, the floating capacitance component occurring between the grand pattern and the remaining conductive films can be preferably reduced.

The input device can be manufactured in a simple method without a need to remove all the unnecessary remaining conductive film.

An input device is provided having a plurality of sensor sections configured to detect an electrostatic capacitance change caused by an input member. The input device includes a conductive film formed on a substrate; a plurality of electrode sections obtained by cutting and partitioning the conductive film in a predetermined shape so as to correspond to the plurality of sensor sections. At least one dividing groove is formed on a remaining portion of the conductive film disposed between the electrode sections, in order to divide the remaining conductive film.

With this configuration, it is possible to reduce the floating capacitance component and thus to improve a reference sensitivity, suppress fluctuation of the reference sensitivity, improve output characteristics during detection, and thereby assuring a stable input operation.

The input device can be manufactured in a simple method without a need to remove all the unnecessary remaining conductive film.

A method of manufacturing an input device is provided in which the input device has a sensor sections configured to detect an electrostatic capacitance change caused by an input member. The method includes the steps of: (a) forming a conductive film on a substrate; (b) forming a partition groove on the conductive film to partition the conductive film in a predetermined shape and thus obtaining electrode sections corresponding to the sensor section; (c) forming at least one dividing groove on a portion of a remaining portion of the conductive film excluding the electrode sections, the portion being disposed between the electrode sections and a ground pattern to be formed later in step (e); (d) forming an insulating film on the remaining conductive film; (e) forming the ground pattern on a portion of the insulating film opposite the remaining conductive film; and (f) after step (d), forming a wiring pattern electrically connected to the electrode sections.

In the manufacturing method, in step (c), the dividing grooves are formed on the remaining electrode film without removing all the remaining film electrodes. Accordingly, it is possible to manufacture an input device having good operation stability in a simple manufacturing method.

In particular, since it is possible to reduce the floating capacitance component in the vicinity of the ground pattern, it is possible to more effectively manufacture the input device having the good operation stability in a simple manufacturing method.

In another aspect, a method of manufacturing an input device is provided in which the input device has a plurality of sensor sections configured to detect an electrostatic capacitance change caused by an input member. The method includes the steps of: (a) forming a conductive film on a substrate; (b) forming a partition groove on the conductive film to partition the conductive film in a predetermined shape and thus obtaining a plurality of electrode sections corresponding to the plurality of sensor sections; (c) forming at least one dividing groove on a remaining portion of the conductive film disposed between the electrode sections; (d) forming an insulating film on the remaining conductive film; and (e) forming a wiring pattern electrically connected to the electrode sections.

In this manufacturing method, in step (c), the dividing grooves are formed on the remaining electrode film without removing all the remaining film electrodes. Accordingly, it is possible to manufacture an input device having good operation stability in a simple manufacturing method.

### BRIEF DESCRIPTION OF THE DRAWINGS

The components in the figures are not necessarily to scale, emphasis instead being placed upon illustrating the principles of the invention. Moreover, in the figures, like referenced numerals designate corresponding parts throughout the different views.

FIG. 1 is a plan view of a touch sensor (input device) according to an embodiment.

FIG. 2 is a plan view (in which an insulating film, a ground pattern, and a wiring pattern shown in FIG. 1 are removed) showing a state of a conductive film formed on a substrate of the touch sensor shown in FIG. 1.

FIG. 3 is a cross-sectional view of the touch sensor shown in FIG. 1 taken along the line III-III.

FIG. 4 is a cross-sectional view of the touch sensor shown in FIG. 1 taken along the line IV-IV.

FIG. 5 is a schematic view illustrating a reference value and an output variation according to an embodiment.

### DESCRIPTION OF THE EMBODIMENTS

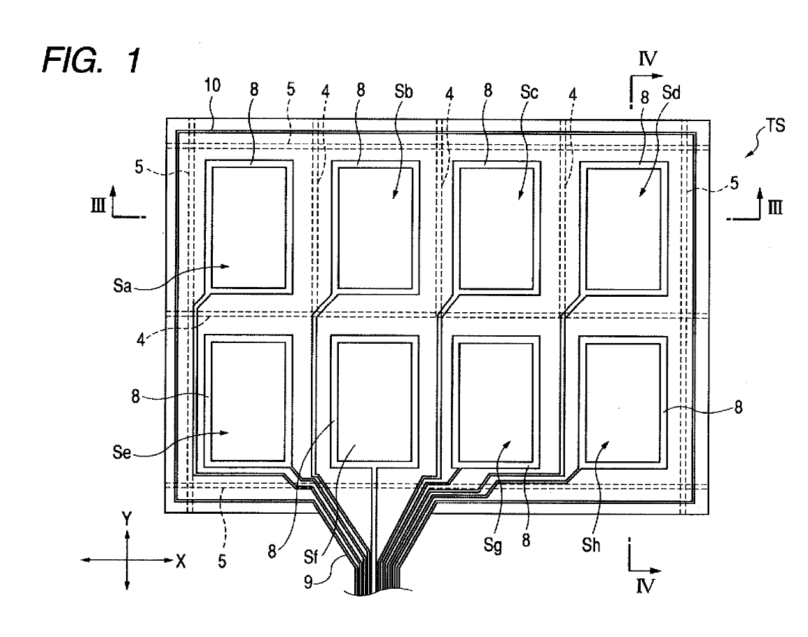

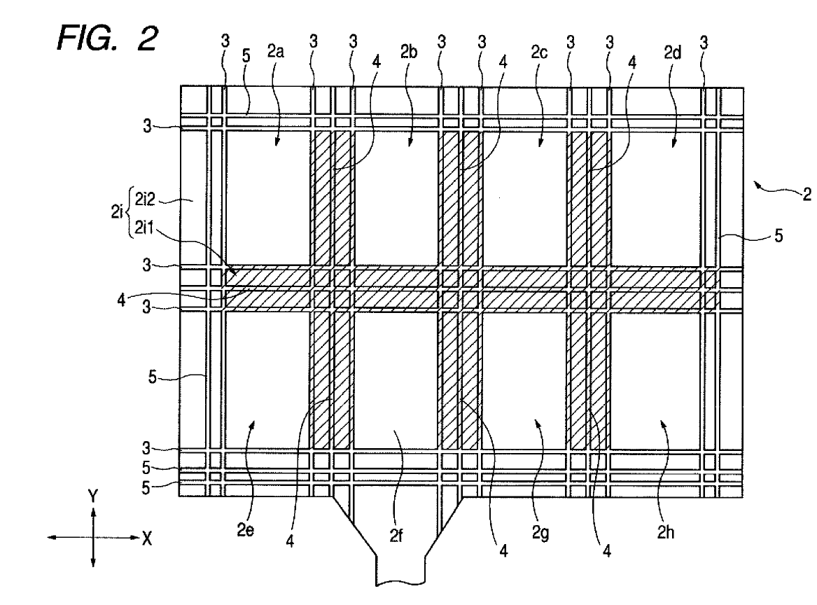

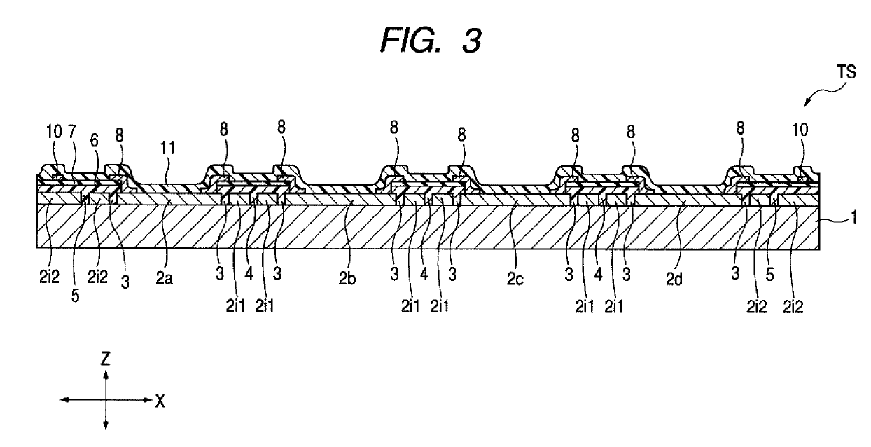

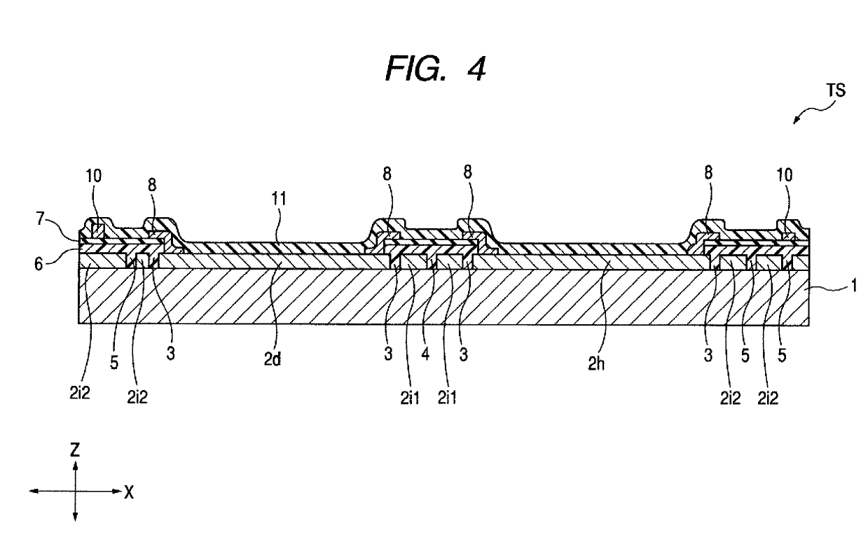

FIG. 1 is a plan view of a touch sensor (input device) according to an embodiment. FIG. 2 is a plan view (in which an insulating film, a ground pattern, and a wiring pattern shown in FIG. 1 are removed) showing a state of a conductive film formed on a substrate of the touch sensor shown in FIG. 1. FIG. 3 is a cross-sectional view of the touch sensor shown in FIG. 1 taken along the line III-III. FIG. 4 is a cross-sectional view of the touch sensor shown in FIG. 1 taken along the line IV-IV.

In FIGS. 1 to 4, an X direction indicates a horizontal direction, a Y direction is a vertical direction, and a Z direction indicates a film thickness direction and each direction is perpendicular to the other two directions.

A touch sensor TS includes a substrate 1, a conductive film 2, insulating films, wiring patterns 8, and a ground pattern 10.

Reference numeral 1 shown in FIGS. 3 and 4 denotes the substrate, which is formed of polyethylene terephthalate (PET), for example.

Since the touch sensor TS can be attached to a curved casing, that is, an attachment flexibility is improved, it is preferable that the substrate 1 is flexible.

The conductive film 2 is formed, for example, on the substrate 1 by screen printing.

As shown in FIG. 2, the conductive film 2 has partition grooves 3 for forming electrode sections 2a to 2h and dividing grooves 4 and 5 for dividing the remaining conductive film 2i excluding the electrode section 2a formed thereon.

As shown in FIG. 2, four linear partition grooves 3 are formed parallel to the vertical direction (the Y direction shown in the figure) along the horizontal direction (the X direction shown in the figure).

As shown in FIG. 2, eight linear partition grooves 3 are formed parallel to the horizontal direction (the X direction shown in the figure) along the vertical direction (the Y direction shown in the figure).

In this configuration, eight electrode sections 2a to 2h are surrounded by the grooves 3 extending in the horizontal direction and the vertical direction.

In the embodiment, the electrode sections 2a to 2h are formed in 4 columns by 2 rows.

Among the remaining conductive film 2i outside the electrode sections 2a to 2h, portions of remaining conductive film 2i disposed between the electrode sections 2a to 2h are marked with diagonal lines in FIG. 2 as first remaining conductive film 2i1.

Remaining conductive film 2i not marked with the diagonal lines are described as second remaining conductive film 2i2 outside electrode forming areas of the electrode sections 2a to 2h.

As shown in FIG. 2, the dividing grooves 4 are disposed on the first remaining conductive film 2i1 in a direction (a direction perpendicular to a direction crossing the electrode sections 2a to 2h) for dividing widths of the electrode sections 2a to 2h.

As shown in FIG. 2, the dividing grooves 5 are disposed on the second remaining conductive film 2i2 in directions for dividing widths between a ground pattern 10 to be described below and the electrode sections 2a to 2h.

The dividing grooves 4 and 5 are linearly formed along the horizontal direction (X direction shown in the figure) or the vertical direction (Y direction shown in the figure).

In other words, the dividing grooves 4 are formed parallel to the electrode sections 2a to 2h and the partition grooves 5 are parallel to the ground pattern 10 and the electrode sections 2a to 2h.

The dividing grooves 4 are formed along the centers of the widths between the electrode sections 2a to 2h.

The dividing grooves 5 are formed along the centers of the widths between the electrode sections and the ground pattern.

As shown in FIGS. 3 and 4, the first remaining conductive film 2i1 and the second remaining conductive film 2i2 are covered with insulating films 6 and 7 such as resistors. Although the insulating films 6 and 7 each have a two-layer structure in FIGS. 3 and 4, each of them may have a one-layer structure or a three-layer structure.

As shown in FIGS. 1, 3, and 4, the electrode sections 2a to 2h are surrounded by wiring patterns 8.formed of Ag.

The wiring patterns 8 are formed from the insulating films 7 to the electrode sections 2a to 2h and are electrically connected to the electrode sections 2a to 2h.

The wiring patterns 8 extend to connector sections 9 of the touch sensor TS as shown in FIG. 1.

As shown in FIG. 1, the ground pattern 10 formed of Ag is formed on the second remaining conductive film 212 shown in FIG. 2 via the insulating films 6 and 7.

The ground pattern 10 extends to the connector sections 9.

The wiring patterns 8, the ground pattern 10, and the electrode sections 2a to 2h are covered with an insulating overcoat film 11 formed of the resistor.

As shown in FIG. 1, eight areas surrounded by the wiring patterns 8 serve as sensor sections Sa to Sh.

The electrode sections 2a to 2h are disposed in the sensor sections Sa to Sh, respectively.

For example, the touch sensor Ts shown in FIG. 1 is mounted the casing and when an operator's body such as a finger touches surfaces of the casing on the sensor sections, the touch sensor Ts is configured to detect an electrostatic capacitance change generated between the operator's body and the electrode sections 2a to 2h.

The dividing grooves 4 and 5 shown in FIG. 2 are marked with a dotted line in FIG. 1.

As shown in FIGS. 1 and 2, the partition grooves 5 dividing the second remaining conductive films 212 are disposed between the ground pattern 10 and the electrode sections 2a to 2h.

The dividing grooves 4 for dividing the first remaining conductive film 2i1 are disposed between the electrode sections 2a to 2h.

The remaining conductive film 2i is minutely partitioned and the remaining conductive film 2i has smaller dimensions by formation of the dividing grooves 4 and 5.

With this configuration, since it is possible to improve the reference sensitivity or suppress the scattering of the reference sensitivity and to achieve the improvement in output variation during the detection by reducing the floating capacitance component, a touch sensor having good operation stability is obtained.

Here, the “reference sensitivity” is determined as a rise of an output to a time before operation of the touch sensor TS (in an initial state when the finger does not touch or approach the sensor sections and the electrostatic capacitance is not changed) and the reference sensitivity is set to a high sensitivity as the rise is sharp.

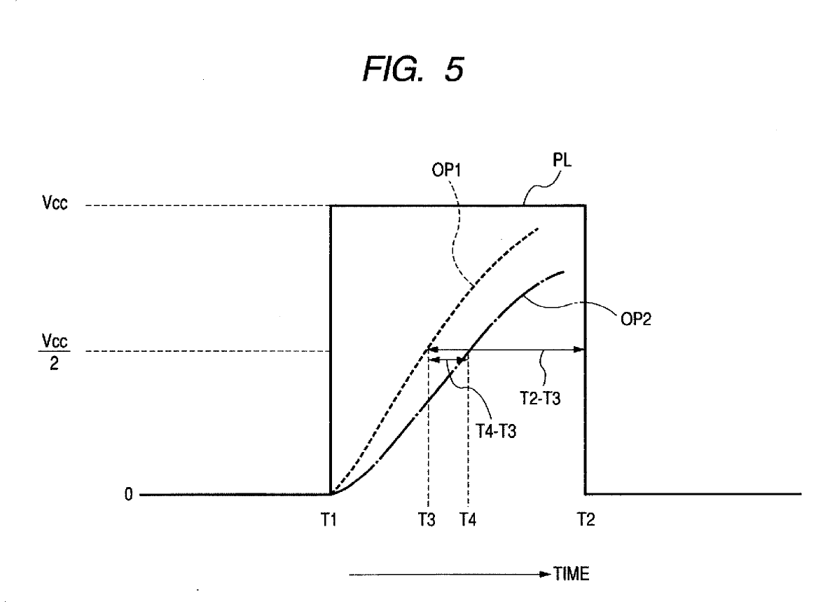

The reference sensitivity is more specifically described with reference to FIG. 5.

As shown in FIG. 5, only a regular pulse signal PL constituted by a predetermined frequency of an amplitude voltage Vcc marked with a solid line shown in FIG. 5 is output to the touch sensor TS from clock signal generating means (not shown).

The pulse signal PL rises from 0V to Vcc at T1 and drops from Vcc to 0V at TS.

At this time, when the pulse signal PL is not output to the all the sensor sections Sa to Sh at the same timing and for example, the pulse signal PL is output to the sensor section Sa, the other sensor sections Sb to Sh have a ground potential.

Now, when the pulse signal PL shown in FIG. 5 is output to the sensor section Sa from the clock signal generating means, an output OP1 marked with the dotted line shown in FIG. 5 can be acquired from the sensor section Sa.

At the time when the output OP1 passes Vcc/2 is set to T3, the reference sensitivity (reference value) is determined as T2-T3.

Since the larger the T2-T3, the sharper the rise of the output OP1, a sensitivity is good, while since the smaller the T2-T3, the smoother, the rise of the output OP1, the sensitivity is lowered.

When an electrostatic capacitance C becomes larger, the rise becomes smoother, but in the embodiment described above, it is possible to reduce the electrostatic capacitance C inherent in the sensor sections Sa to Sh from the start by reducing the floating capacitance component, whereby it is possible to set the reference sensitivity to a high sensitivity.

When the finger touches or approaches the touch sensor TS, the electrostatic capacitance is changed between the electrode section 2a corresponding to the sensor section Sa and the finger.

The electrostatic capacitance becomes larger in the change of the electrostatic capacitance. As shown in FIG. 5, the rise of the output value OP2 during the detection to a time becomes smoother than the rise the output value OP1 in the initial state to the time, and thus, the output value OP2 passes Vcc/2 at a time T2 later than the output value OP1.

A time T4-T3 serves as the output variation and since it is possible to set the reference sensitivity to the high sensitivity, it is possible to increase the output variation in the embodiment.

Although Vcc/2 is used as a threshold value in FIG. 5, other another threshold value may be set.

In this embodiment, it is possible to reduce the floating capacitance component with respect to each of the sensor sections Sa to Sh by dividing the first remaining conductive film 2i1 and the second remaining conductive film 2i2 outside the electrode sections 2a to 2h by means of the dividing grooves 4 and 5, whereby it is possible to improve the reference sensitivity and to reduce the scattering the reference sensitivity.

In the embodiment, as shown in FIGS. 1 to 4, the dividing grooves 4 formed on the first remaining conductive film 2i1 are disposed in a direction (in parallel to the electrode sections 2a to 2h) in order to divide the widths of the electrode sections.

The dividing grooves 5, formed on the second remaining conductive film 2i2, are disposed in a direction (in parallel to the electrode sections 2a to 2h and the ground pattern 10) in order to divide the widths between the electrode sections 2a to 2h and the ground pattern 10.

It is preferable that the dividing grooves 4 and 5 are formed along the centers of the widths.

With this configuration, since it is possible to properly reduce the floating capacitance component and to effectively suppress the dimensions of the remaining conductive film 2i opposite each other via the partition grooves 3 in the electrode sections 2a to 2h, it is possible to reduce coupling of the floating capacitance component with the sensor sections Sa to Sh so as to achieve the an improvement in reference sensitivity.

The dividing grooves 4 and 5 are disposed in the directions to divide the widths so as to simply and properly form the dividing grooves 4 and 5 by means of the laser.

The linear dividing grooves 4 and 5 are disposed along the centers of the widths and thus, it is possible to reduce an influence of the floating capacitance component evenly in the sensor sections Sa to Sh so as to more suitably improve the operation stability of the touch sensor TS.

The dividing grooves 4 and 5 are linearly formed so as to form the dividing grooves 4 and 5.

The influence of the electrostatic capacitance occurring between the ground pattern 10 and the second remaining conductive film 2i2 becomes stronger in the vicinity of the ground pattern 10, but since the second remaining conductive film 2i2 are minutely divided by means of the dividing grooves 5 at a position located between the ground pattern 10 and the electrode sections 2a to 2h as described, it is possible to suitably reduce the floating capacitance component generated in the vicinity of the ground pattern 10.

It is possible to properly select whether the touch sensor TS is used with the touch sensor mounted in the casing (an operation surface of the operator's body such as the finger corresponds to the surface of the casing) or the touch sensor is used by exposing the surface of the touch sensor TS as the operation surface depending on a use.

When the touch sensor TS is mounted in the casing, it is possible to arbitrarily determine which surface (the surface of an overcoat film 11 or a rear surface of the substrate 1) of the touch sensor TS shown in FIGS. 3 and 4 is mounted.

For example, when the touch sensor TS is mounted in a liquid crystal display screen and the touch sensor TS is transparently marked, that is, a transparency is required, it is necessary to form the substrate 1, the insulating films 6 and 7, and the overcoat film 11 by highly transparent materials and to form the conductive film 2 by a transparent conductive film.

The transparent conductive film may be formed of PEDOT (3,4-ethylenedioxythiophene).

Since an optical transmittance of the touch sensor TS can be prescribed in accordance with usage, it is possible to use a semi-transparent insulating film or conductive film.

The wiring patterns 8 are configured to surround the electrode sections 2a to 2h as shown in FIG. 1. However, the wiring patterns 8 may be formed on only one side of each of the electrode sections 2a to 2h, that is, the wiring patterns 8 are not limited to the surrounding shape.

One dividing groove 4 and one dividing groove 5 are disposed between the electrode sections 2a to 2h and between the electrode sections 2a to 2b and the ground pattern 10, respectively in the embodiment shown in FIGS. 1 to 4, but two or more dividing grooves may be also be provided.

In one embodiment, the dividing grooves 4 and 5 are disposed in only one of the remaining conductive film 2i1 and 2i2 in addition to both the first remaining conductive film 2i1 and the second remaining conductive film 2i2. However in another embodiment, it is more preferable that the dividing grooves 4 and 5 are formed in both the first remaining conductive film 2i1 and the second remaining conductive film 2i2.

In one embodiment, the dividing grooves 5 are disposed in only a part of the ground pattern 10 in addition to the entire circumference of the ground pattern 10. The dividing grooves 4 may be disposed in only the first remaining conductive film 2i1 between the electrode sections on one location. However, it is more preferable that the dividing grooves 5 be disposed parallel to the entire circumference (excluding a portion close to the connector section 9) of the ground pattern 10 and the dividing grooves 4 be disposed in the first remaining conductive film 2i1 disposed between the electrode sections as shown in FIGS. 1 and 2.

The ground pattern 10 may be electrically connected onto the second remaining conductive film 2i2.

Planar shapes of the electrode sections 2a to 2h are not limited to rectangular shapes. For example, the planar shapes of the electrode sections 2a to 2h may be circular or elliptical.

In one exemplary embodiment, the wiring patterns 8, the ground pattern 10, the insulating films 6 and 7, and the conductive film are sequentially laminated on the substrate 1 from the bottom, that is, they may be laminated in a reverse order of the order of the embodiment described in FIGS. 3 and 4. However, the lamination order shown in FIGS. 3 and 4 is more preferable so as to reduce an influence on other layers when the partition grooves 3 and the dividing grooves 4 and 5 are processed by the laser or to form the conductive film 2 more flatly.

In a manufacturing method of the touch panel TS according to the embodiment of the invention, the conductive film 2 are formed on the entire surface of the substrate 1 by screen printing and then, the partition grooves 3 and the dividing grooves 4 and 5 shown in FIG. 2 are formed on the conductive film 2 by means of the laser.

As shown in FIGS. 3 and 4, the insulating films 6 and 7 are formed on the remaining conductive film 2i , the wiring patterns 8 and the ground pattern 10, and finally, the overcoat film 11 shown in FIGS. 3 and 4 is formed.

In the manufacturing method of the touch panel TS according to this embodiment, since it is possible to improve the reference sensitivity and suppress the scattering of the reference sensitivity, and to achieve the improvement in output variation without removing all unnecessary remaining conductive , it is possible to easily manufacture a touch sensor TS having the good operation stability.

The partition grooves 3 and the dividing grooves 4 and 5 are formed on the remaining conductive films 2i by means of the laser. The partition grooves 3 and the dividing grooves 4 and 5 may also be formed, for example, by etching instead of the laser.

However, it is more preferable to use the laser so as to easily form the partition grooves 3 and the dividing grooves 4 and 5.

When the partition grooves 3 are linearly formed on the conductive film 2 in the horizontal direction and in the vertical direction by means of the plurality of lasers and the dividing grooves 4 and 5 are formed parallel to the partition grooves 3 in the directions for dividing the widths of the remaining conductive film 2i positioned between the ground pattern 10 and the electrode sections 2a to 2h and between the electrode sections 2a to 2h by means of the laser as shown in FIG. 2, all the grooves 3 to 5 are formed only in a linear shape. Accordingly, it is possible to easily form the grooves 3 to 5 by means of the laser.

### EXAMPLES

The data below shows the reference sensitivity and the output variation of the touch sensor according to the Example shown in FIGS. 1 to 4 and a reference sensitivity and an output variation of a touch panel according to comparative examples.

In touch sensors described in Comparative Examples 1 to 3, the dividing grooves 4 and 5 shown in FIG. 2 are not disposed on the conductive film. In the touch sensor described in Example 1, the dividing grooves 4 and 5 are disposed on the conductive films in the same manner as FIG. 2.

In Example 1 and Comparative Examples 1 to 3, other configurations and test conditions are standardized in consideration of a difference in the presence or absence of the dividing grooves 4 and 5.

TABLE 1

| Reference value (T2-T3) | | | | | | | | | Output variation (T4-T3) | | | | | | | | |
|---|---|---|---|---|---|---|---|---|---|---|---|---|---|---|---|---|---|
| | Sh | Sd | Sg | Sc | Sf | Sb | Se | Sa | | Sh | Sd | Sg | Sc | Sf | Sb | Se | Sa |
| Com 1 | 45 | 42 | 299 | 271 | 391 | 248 | 284 | 0 | Com 1 | 35 | 34 | 35 | 36 | 32 | 36 | 32 | 0 |
| Com 2 | 84 | 60 | 320 | 278 | 418 | 271 | 322 | 1 | Com 2 | 32 | 35 | 34 | 34 | 32 | 33 | 33 | 1 |
| Com 3 | 48 | 34 | 295 | 264 | 399 | 260 | 300 | 0 | Com 3 | 23 | 20 | 35 | 35 | 33 | 32 | 34 | 0 |
| Ex 1 | 697 | 666 | 698 | 698 | 722 | 690 | 692 | 667 | Ex 1 | 38 | 35 | 34 | 36 | 34 | 34 | 34 | 36 |

A reference value shown in Table 1 corresponds to a value of T2-T3 shown in FIG. 5 and an output variation shown in Table 1 corresponds to a value of T4-T3 shown in FIG. 5.

The reference value is larger and the rise of an output to a time shown in FIG. 5 is sharper. This means that the sensitivity is good.

Sa to Sh shown in Table 1 represents the sensor sections Sa to Sh shown in FIG. 1.

As shown in FIG. 1, in Comparative Examples 1 to 3, reference values in the sensor sections Sa, Sd, and Sh become smaller and the reference sensitivity is greatly reduced.

In particular, the reference value of the sensor section Sa in Comparative Examples 1 to 3 is 0 or 1 and since the rise of the output is very gentle and the output variation is also 0 or 1, it is difficult to detect the electrostatic capacitance change.

Since two sides of each of the sensor sections Sa, Sd, and Sh are disposed close to the ground pattern 10, electrostatic capacitances inherent in the sensor sections Sa, Sd, and Sh acquiring the floating capacitance components in the vicinity of the ground pattern 10 are significantly higher than those of other sensor sections from the start.

On the other hand, in Example 1, since the reference values in all the sensor sections Sa to Sh can be larger than those in Comparative Examples 1 to 3, it is possible to improve the reference sensitivity and to suppress the scattering of the reference sensitivity.

Since the output variation in the sensor section Sa which has 0 or 1 in Comparative Examples 1 to 3 can be as large as the output variations in other sensor sections and the output variations in the sensor sections Sa to Sh can be evenly large, the operation stability in Example 1 is better than those in Comparative Examples 1 to 3.

Next, a touch sensor in which the second remaining conductive film 2i2 is removed in the Example shown in FIG. 2 is manufactured as Reference Example 1.

The touch sensor according to the Example shown in FIGS. 1 to 4 is manufactured as Example 2.

In Example 2 and Reference Example 1, other configurations and test conditions are standardized only in consideration of the presence or absence of the second remaining conductive film.

TABLE 2

| Reference value (T2-T3) | | | | | | | | | Output variation (T4-T3) | | | | | | | | |
|---|---|---|---|---|---|---|---|---|---|---|---|---|---|---|---|---|---|
| | Sh | Sd | Sg | Sc | Sf | Sb | Se | Sa | | Sh | Sd | Sg | Sc | Sf | Sb | Se | Sa |
| Ex 2 | 414 | 330 | 511 | 476 | 575 | 466 | 487 | 429 | Ex 2 | 69 | 67 | 66 | 69 | 66 | 66 | 64 | 62 |
| Ref 1 | 427 | 362 | 517 | 490 | 575 | 471 | 485 | 471 | Ref 1 | 60 | 59 | 66 | 59 | 63 | 62 | 63 | 61 |

As shown in Table 2, the reference values and the output variations in Example 2 and Reference Example 1 are equal to each other.

Accordingly, it is effective to dispose the dividing grooves without removing all the remaining conductive film.

What is claimed is:

1. An input device having a sensor section configured to detect an electrostatic capacitance change by an input member, the input device comprising:
a conductive film formed on a substrate;
the conductive film cut and partitioned in a predetermined shape so as to correspond to the sensor section to provide an electrode section;
a ground pattern disposed at a position located, in the film thickness direction, opposite a remaining portion of the conductive film excluding the electrode sections; and
at least one dividing groove formed on a portion of the remaining conductive film disposed between the ground pattern and the electrode sections, to divide the remaining conductive film.

2. An input device having a plurality of sensor sections configured to detect an electrostatic capacitance change caused by an input member, the input device comprising:
a conductive film formed on a substrate;
the conductive film cut and partitioned in a predetermined shape so as to correspond to the plurality of sensor sections to provide a plurality of electrode sections; and
at least one dividing groove formed on a remaining portion of the conductive film disposed between the electrode sections, to divide the remaining conductive film.

3. The input device according to claim 2,
wherein a ground pattern is disposed at a position located, in the film thickness direction, opposite the remaining conductive film outside an electrode formation area, the electrode formation area having the plurality of electrode sections formed thereon, and
wherein at least one dividing groove is formed on a portion of the remaining conductive film disposed between the ground pattern and the electrode sections, to divide the remaining conductive film.

4. The input device according to claim 3,
wherein the plurality of electrode sections are arranged in a matrix,
wherein the ground pattern is disposed at a position located, in the film thickness direction, opposite a portion of the remaining conductive film disposed outside an electrode formation area, the electrode formation area having the plurality of electrode sections formed thereon, and
wherein the dividing groove is formed on the portion of the remaining conductive film disposed between the electrode sections and the portion of the remaining conductive film disposed outside the electrode formation area.

5. The input device according to claim 1, wherein the dividing groove is formed on the remaining conductive film in the direction for dividing at least one of the width of the remaining conductive film between the electrode sections or the width of the remaining conductive film between the ground pattern and the electrode sections.

6. The input device according to claim 5, wherein the dividing groove is formed at least on the center of the width of the remaining conductive film.

7. The input device according to claim 1, wherein the dividing groove is linear.

8. The input device according to claim 1, wherein the conductive film is a transparent conductive film.

9. A method of manufacturing an input device having a sensor sections configured to detect an electrostatic capacitance change caused by an input member, the method comprising the steps of:
(a) forming a conductive film on a substrate;
(b) forming a partition groove on the conductive film to partition the conductive film in a predetermined shape and obtaining electrode sections corresponding to the sensor section;
(c) forming at least one dividing groove on a portion of a remaining portion of the conductive film excluding the electrode sections, the portion being disposed between the electrode sections and a ground pattern to be formed later in step (e);
(d) forming an insulating film on the remaining conductive film;
(e) forming the ground pattern on a portion of the insulating film opposite the remaining conductive film; and
(f) after step (d), forming a wiring pattern electrically connected to the electrode sections.

10. A method of manufacturing an input device having a plurality of sensor sections configured to detect an electrostatic capacitance change caused by an input member, the method comprising the steps of:
(a) forming a conductive film on a substrate;
(b) forming a partition groove on the conductive film to partition the conductive film in a predetermined shape and obtaining a plurality of electrode sections corresponding to the plurality of sensor sections;
(c) forming at least one dividing groove on a remaining portion of the conductive film disposed between the electrode sections;
(d) forming an insulating film on the remaining conductive film; and
(e) forming a wiring pattern electrically connected to the electrode sections.

11. The method of manufacturing an input device according to claim 10 further comprising:
(f) after step (d), forming the ground pattern on a portion of the insulating film opposite the portion of the remaining conductive film disposed outside an electrode formation area, the electrode formation area having the plurality of electrode sections formed thereon; and
wherein in step (c), at least one dividing groove is formed on the remaining portion of the conductive film disposed between the electrode sections and the ground pattern formed in step (f).

12. The method of manufacturing an input device according to claim 9, wherein the partition groove and the dividing groove are formed by laser irradiation.

13. The method of manufacturing an input device according to claim 12, wherein the partition groove is linearly formed on the conductive film in a matrix by a plurality of laser irradiations, and the dividing groove is formed on the remaining conductive film in the direction for dividing at least one of the width of the remaining conductive film between the electrode sections or the width of the remaining conductive film between the ground pattern and the electrode sections, and wherein the dividing groove is formed together with the partition groove by the laser irradiations.
